(19) United States
(12) Patent Application Publication
(10) Pub. No.: US 2010/0319747 A1
(43) Pub. Date: Dec. 23, 2010

(54) Integrated Thermal Electric Generator with Heat Storage Unit

(76) Inventors: Mark Y. Wong, Union City, CA (US); Leo Y. Kwok, Milpitas, CA (US)

Correspondence Address: James M. Wu;JW Law Group, 84 W. Santa Clara Street, Suite 820, San Jose, CA, 95113, US

(21) Appl. No.: 12/817,657

(22) Filed: Jun. 17, 2010

Related U.S. Application Data
(60) Provisional application No. 61/218,578, filed on Jun. 19, 2009.

(51) Int. Cl. H01L 35/34; H01L 35/30; H01L 21/30

(52) U.S. Cl. 136/201; 136/205; 438/54; 257/E21.211

(57) ABSTRACT

A multi-layered solid-state thermal-electrical generator (“MSTEG”) system capable of generating electricity from thermal energy is disclosed. An MSTEG system includes a thermal layer, a regulating layer, and a storage layer. The thermal layer, in one embodiment, includes multiple integrated thermal-electrical generator (“ITEG”) devices configured to generate electricity in response to a certain thermal condition. The thermal condition for example can be a temperature difference between 900° C. (Celsius) to 1200° C. for a certain layer. The regulating layer includes multiple thermal regulators deposited over the thermal layer, wherein the thermal regulators regulate temperature. The storage layer includes one or more thermal storage tanks deposited over the regulating layer, wherein each thermal storage tank is capable of storing heat.

### PRIORITY

This application claims the benefit of priority based upon U.S. Provisional Patent Application Ser. No. 61/218,578, filed on Jun. 19, 2009 in the name of the same inventor and entitled “INTEGRATED THERMAL ELECTRIC GENERATOR WITH HEAT STORAGE SYSTEM,” hereby incorporated into the present application by reference.

### FIELD

The technical field of embodiments of the present invention relate to power generation. More specifically, embodiments of the present invention relate to converting thermal energy to electrical energy.

### BACKGROUND

With increasing demand of energy, alternative energy source other than fossil fuel becomes vital aspect of future energy supply. The thermal-electric energy is an alternative energy source that is capable of converting, for instance, heat energy to electricity. A conventional thermoelectric generator is able to generate electricity when different temperatures are present between two media. Upon the presence of a temperature gradient in a medium, charged carriers such as electrons diffuse or migrate from one temperature zone to another temperature zone.

Conventional thermal-electrical generator (“TEG”) devices collect heat energy from a thermal energy source such as solar energy to produce steam from heating up the water wherein the steam subsequently energizes mechanical turbines to generate electricity. The TEG cells typically require high level of maintenance with many mechanical moving parts. With large physical dimension and relatively low power output, conventional TEG cells are typically unattractive as an alternative power source.

A problem associated with a typical TEG cell is that the heat provided by a thermal energy source may not be consistent. For example, with heat diminishes due to Sun set or cloudy day, the power output drops dramatically. After a bright and sunny sky followed by a cloudy sky, the same level of power output from a TEG cell typically can not be maintained due to lack of sustained heat supply. In addition, the output power generated from a TEG system may be dropped and eventually stopped when the heat source is removed for example during night time. In order to remedy such deficiency, a conventional approach is to use external battery to store the excess energy generated during the day time and retrieve the stored electrical energy at night time. External battery can add extra complication as well as overall system cost.

### SUMMARY

A method and multi-layered solid-state thermal-electrical generator (“MSTEG”) system capable of generating electricity from thermal energy are disclosed. An MSTEG system includes a thermal layer, a regulating layer, and a storage layer. The thermal layer, in one embodiment, includes multiple integrated thermal-electrical generator (“ITEG”) devices configured to generate electricity in response to certain thermal condition. The thermal condition can be a temperature range from 200° C. (Celsius) or lower to 1200° C. or even higher depending on the types of ITEG devices used. The regulating layer includes multiple thermal regulators deposited over the thermal layer, wherein the thermal regulators regulate temperature. The storage layer includes one or more thermal storage tanks deposited over the regulating layer, wherein each thermal storage tank is capable of storing heat.

Additional features and benefits of the exemplary embodiment(s) of the present invention will become apparent from the detailed description, figures and claims set forth below.

### BRIEF DESCRIPTION OF THE DRAWINGS

Exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is a block diagram illustrating an MSTEG system using ITEG devices in accordance with one embodiment of the present invention;

FIG. 2 is a block diagram illustrating an MSTEG system using ITEG devices capable of operating at various temperature zones in accordance with one embodiment of the present invention;

FIG. 3 is a block diagram illustrating an MSTEG system using ITEG devices having multiple thermal storage layers in accordance with one embodiment of the present invention;

FIG. 4 is a block diagram illustrating an MSTEG system using ITEG devices having multiple thermal storage tanks capable of operating in various temperature zones in accordance with one embodiment of the present invention;

FIG. 5 is a block diagram illustrating an MSTEG system using multiple thermal chambers and ITEG devices in accordance with one embodiment of the present invention;

FIG. 6 is a block diagram illustrating an MSTEG system using ITEG devices with thermal sensors for monitoring temperature between the layers in accordance with one embodiment of the present invention;

FIG. 7 is a three-dimensional (“3D”) diagram illustrating an MSTEG system using ITEG devices in accordance with one embodiment of the present invention;

FIG. 8 is a block diagram illustrating a layout of ITEG using multiple thermal electric generator (“TEG”) devices in accordance with one embodiment of the present invention;

FIG. 9 is a block diagram illustrating an array of TEG cells connected with a combination of series and parallel connections in accordance with one embodiment of the present invention;

FIG. 10 is flowcharts illustrating a process for generating electricity via thermal energy through an MSTEG system in accordance with one embodiment of the present invention; and

FIG. 11 is flowcharts illustrating a process for fabricating an MSTEG system in accordance with one embodiment of the present invention.

### DETAILED DESCRIPTION

Exemplary embodiment(s) of the present invention is described herein in the context of a method, system and apparatus of generating electricity from thermal energy using a multi-layered solid-state thermal-electric generator using ITEG devices.

Those of ordinary skills in the art will realize that the following detailed description of the exemplary embodiment(s) is illustrative only and is not intended to be in any way limiting. Other embodiments will readily suggest themselves to such skilled persons having the benefit of this disclosure. Reference will now be made in detail to implementations of the exemplary embodiment(s) as illustrated in the accompanying drawings. The same reference indicators will be used throughout the drawings and the following detailed description to refer to the same or like parts.

References to “one embodiment,” “an embodiment,” “example embodiment,” “various embodiments,” “exemplary embodiment,” “one aspect,” “an aspect,” “exemplary aspect,” “various aspects,” et cetera, indicate that the embodiment(s) of the invention so described may include a particular feature, structure, or characteristic, but not every embodiment necessarily includes the particular feature, structure, or characteristic. Further, repeated use of the phrase “in one embodiment” does not necessarily refer to the same embodiment, although it may.

In the interest of clarity, not all of the routine features of the implementations described herein are shown and described. It will, of course, be understood that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be understood that such a development effort might be complex and time-consuming, but would nevertheless be a routine undertaking of engineering for those of ordinary skills in the art having the benefit of this disclosure.

Reference will now be made in detail to the embodiments of the present invention, the Integrated Thermal Electric Generator & Storage Systems. While the present invention may describe in conjunction with embodiments, it will be understood that they are not intended to limit the invention to these embodiments. On the contrary, the embodiments of the present invention is intended to cover alternatives, modifications and equivalents, which may be included within the spirit and scope of the invention as defined by the claims, specification, and drawings.

Embodiment(s) of the present invention discloses a multi-layered solid-state thermal-electrical generator (“MSTEG”) system capable of generating electricity from thermal energy. An MSTEG system includes a thermal layer, a regulating layer, and a storage layer. The thermal layer, in one embodiment, includes multiple integrated thermal-electrical generator (“ITEG”) devices configured to generate electricity in response to a thermal condition. The thermal condition can be a temperature range between T_{N} and T_{N-1} for one of the designated thermal layers. The regulating layer includes multiple thermal regulators deposited over the thermal layer, wherein the thermal regulators regulate temperature. The storage layer includes one or more thermal storage tanks deposited over the regulating layer, wherein each thermal storage tank is capable of storing heat.

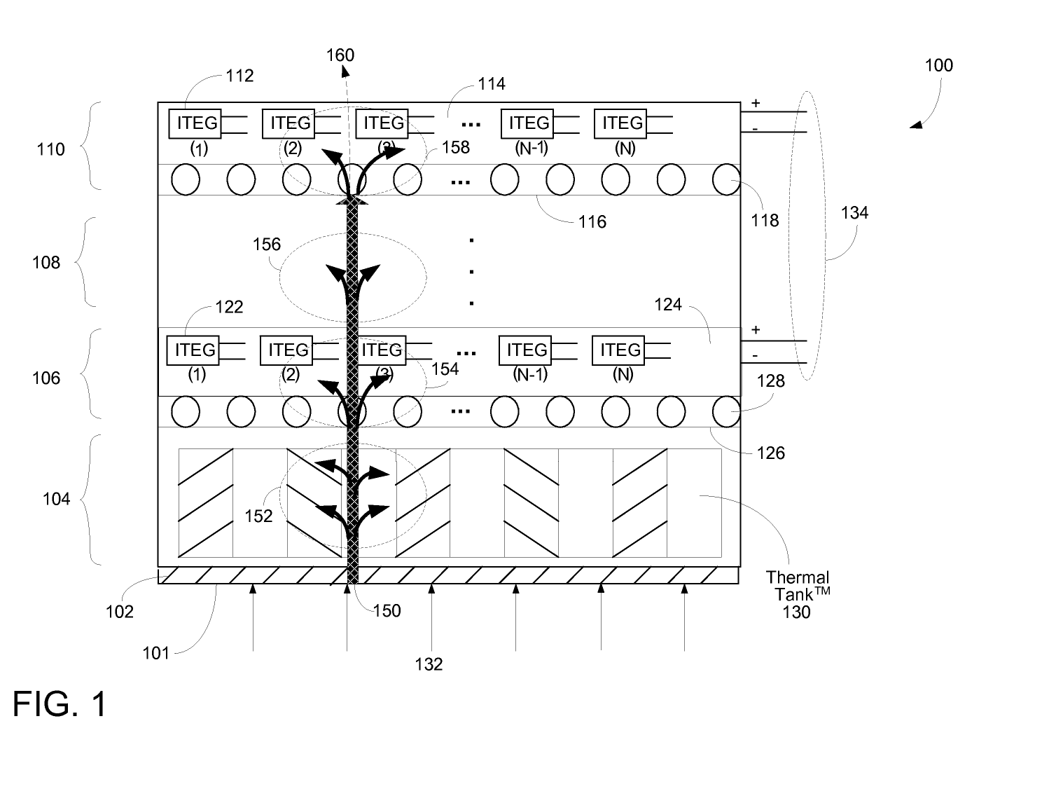

FIG. 1 is a block diagram 100 illustrating an MSTEG system using ITEG devices in accordance with one embodiment of the present invention. Diagram 100 illustrate an thermal energy source 132 and an MSTEG system wherein the MSTEG system includes a heat collecting surface 102, a thermal storage plane 104, a first thermal plane 106, a second thermal plane 110. Thermal energy source 132 can be solar thermal radiation, geo-thermal, and/or manmade heat sources. Note that an additional thermal plane or planes may be deposited or added in an area of 108. It should be noted that the underlying concept of the embodiment does not change if one or more planes and/or layers were added to or removed from diagram 100.

Heat collection surface 102 is a surface area of the MSTEG system that is exposed to an external heat source or external thermal energy source 132. A function of heat collection surface 102 is to absorb thermal energy at a heat exposing side 101 of surface 102 and subsequently pass the absorbed heat from surface 102 to planes 104-110. Note that external thermal energy source 132 includes a form of solar thermal energy, geo-thermal, manmade heat sources, bio-mess thermal reactors, or a combination of solar energy, geo-thermal, manmade heat sources, and bio-mess thermal reactors. Heat collection surface 102, for example, can be fabricated with heat-absorbing materials, such as aluminum, copper, carbon, boron carbide, silicon carbide, titanium, and a compound of one or more of aluminum, copper, titanium, carbon, boron carbide, silicon carbide.

Thermal storage plane 104 includes one or more heat absorbing layers capable of storing heat or thermal energy for a period of time. In one aspect, thermal storage plane 104 includes one or more Thermal Tank™ which is referred to as thermal battery, thermal tank, heat reservoir, or heat storage. Thermal storage plane 104 can further include an insulation layer and a storage layer wherein the storage layer may be divided into multiple sub-layers or blocks for storing heat. Different sub-layer or block in the thermal storage plane 104 stores heat with different temperatures. While the storage layer(s) captures the heat, the insulation layer performs a function of maintaining or housing the heat.

After absorbing certain amount of thermal energy (or heat), a portion or a block of thermal tank may or may not, for example, change its physical form from a solid state to a liquid state for holding the heat. The stored heat is released at a later time when external thermal source 132 is no longer available. Thermal storage plane 104, in one example, can be fabricated with heat-absorbing materials and/or phase change materials, such as aluminum, copper, carbon, boron carbide, silicon carbide, titanium, and a compound of one or more of aluminum, copper, titanium, carbon, boron carbide, and/or silicon carbide. Note that the placement of the Thermal Tank™ can be at the bottom or side of the MSTEG system depending on applications.

First thermal plane 106 includes a regulating layer 126 and a thermal layer 124 wherein regulating layer 126 includes one or more regulators 128. Regulator 128 regulates temperature at thermal layer 124 and guides excessive heat to bypass thermal layer 124. In one embodiment, regulating layer 126 includes an array of regulators 128 to facilitate heat management. Regulators 128 may be manufactured by Microelectronic Mechanical Systems (“MEMS”) devices via semiconductor fabrication process. Alternatively, regulators 128 can also be manufactured by temperature-dependent compound materials able to facilitate heat passage in accordance with the temperature of heat.

Thermal layer 124 includes a thermal chamber containing an M×N matrix of ITEG devices 122, where M and N are integers. Each ITEG device 122, which will be discussed more detail later, is configured to generate electricity in response to the ambient temperature surrounding the ITEG devices 122. In one embodiment, ITEG devices 122 situated in thermal layer 124 are configured to operate in optimal efficiency within a specific range of temperature such as a temperature range between 500° C. and 700° C.

Outputs of electricity from planes 106-110 are fed to a power grid 134 for power output. Power grid 134, also known as output circuit, power output unit, power converter device, and the like, is able to output various output voltages, such as 6 volts (“V”), 12 V, or 18 V. Alternatively, output grid 134 provides DC (direct current) power, AC (alternating current) power, and/or both DC and AC power. Note that power grid 134 may be programmable for selecting a specific set of voltage level.

Similarly, second thermal plane 110 includes a regulating layer 116 and a thermal layer 114 wherein regulating layer 116 includes one or more regulators 118. Regulator 118, similar to regulator 128, regulates temperature at thermal layer 114 and guides excessive heat to bypass thermal layer 114. Regulating layer 116 includes an array of regulators 118 to facilitate heat management. Regulators 118, as regulator 128, may be manufactured using MEMS technology via semiconductor fabrication process. Alternatively, regulators 128 can also be manufactured temperature-dependent materials to facilitate heat passage in response to temperature of the heat. Thermal layer 114 includes a thermal chamber containing an M×N matrix of ITEG devices 112. Each ITEG device 112 is configured to generate electricity in response to the ambient temperature surrounding the ITEG device.

Area 108 indicates that additional thermal planes as well as storage planes can be added depending on the applications.

In one embodiment, the MSTEG system further includes one or more thermal channels 150 which allow heat to travel or bypass one or more planes or layers before reaching its destination. Thermal channel 150 is configured to transport different amount heat 152-160 to different layers and/or planes. When, for example, the MSTEG system is overheating, thermal channel 150 releases extra heat 160 from the system to cool down the system.

The MSTEG system includes multiple thermal chambers and multiple ITEG devices separated by multiple thermal regulators. The MSTEG system further includes Thermal Tank™ design to contain thermal storage layers or columns for thermal storage reservoirs. After absorbing thermal energy from thermal source 132, heat energy enters into the thermal chamber where Thermal Tank™ 130 resides. The heat eventually reaches the first level of thermal regulator 128 which controls heat supplying to ITEG devices 122 for generating electricity. When temperature of the heat matches its thermal electric material characteristics, optimum efficiency of thermal-electrical conversion is reached. The excessive heat enters into the next level of thermal chamber from which the ITEG devices of the next layer generates electricity at its optimum efficiency. Thermal regulators 118 or 128 are used to regulate the heat whereby an improved and better efficiency of thermal-electrical conversion for each layer 114 or 124 can be achieved.

Referring to FIG. 1, when external heat source 132 is present, the heat is collected at heat collecting surface 102 and then the heat travels to Thermal Tank™ 130. Depending on the capacity of Thermal Tank™ 130, the heat can be stored for later use. In one example, a portion of heat enters Thermal Tank™ 130 while another portion of heat continues its path to different layers. Alternatively, no heat travels to layers 124 or 114 until Thermal Tank™ 130 is fully charged or stored.

When external heat source 132 is diminished and/or disappeared, stored heat is released from Thermal Tank™ 130 to ITEG devices 112 or 122 in layers 114 or 124. Note that the stored heat enables the MSTEG system to continue generating electricity after external heat source 132 is absent. The duration of heat releasing from Thermal Tank™ 130 depends on the specific heat capacity of the medium used in Thermal Tank™ 130 as well as the size or capacity of Thermal Tank™ 130. For example, if the MSTEG system is used in a place where heat source is present most of the time, a Thermal Tank™ 130 with small capacity may be employed to reduce the overall system size and cost while still can maintain sufficient power output throughout the day. A Thermal Tank™ 130 with large capacity may be used to maintain continuous output power from the system if the MSTEG system is used in a place where the heat source disappears periodically such as the solar source.

Alternatively, Thermal Tank™ 130 further smoothes power output by reducing power fluctuations such as power surge. Power fluctuation can harm electrical components and/or appliances. For example, power may fluctuate when the heat supply suddenly becomes unavailable after absence for a certain period of time. Note that the capacity of Thermal Tank™ 130 used in an MSTEG system can be application specific. Thermal Tank™ 130 allows an MSTEG system to generate electricity for a prolong period of time after disappearing of heat source 132.

During an operation, when heat source 132 is present, Thermal Tank™ 130 stores the heat energy inside its medium which has a specific heat capacity built with heat absorption materials. When the external heat disappears or slowly diminishes over time, the heat energy stored in the Thermal Tank™ releases the heat to compensate the heat loss from the diminished external heat source. The amount of heat stored in the Thermal Tank™ depends on the size and thermal materials used in the design as dictated by specific requirement. In one aspect, an MSTEG system is designed in such a way that the system can continuously output electricity on 24-hour basis. In addition, Thermal Tank™ 130 eliminates or reduces power surge when amount of heat produced by heat source 134 fluctuates over time.

An MSTEG system, in one aspect, capable of generating electricity in response to an external thermal source includes a first thermal layer, a first regulating layer, and a first storage layer. The first thermal layer includes multiple first ITEG devices configured to generate electricity in response to a first thermal condition. The first ITEG devices are organized in an array configuration having at least a portion of the first ITEG devices are connected in series. Alternatively, many first ITEG devices are organized in an array configuration having at least a portion of the first ITEG devices are connected in parallel. Note that the first thermal condition is the temperature associated with the first thermal layer.

A first regulating layer includes multiple thermal regulators deposited over the first thermal layer. The multiple thermal regulators regulate temperature or a range of temperatures. The thermal regulators include thermal sensors capable of detecting and/or monitoring temperature. The thermal regulators regulate temperature associated with the first thermal layer.

The first storage layer includes one or more first thermal storage tanks deposited over the first regulating layer, wherein each first thermal storage tank is capable of storing heat. In one embodiment, the MSTEG system further includes a second thermal layer, a second regulating layer and a second storage layer. The second thermal layer includes second ITEG devices configured to generate electricity in response to a second thermal condition. The second thermal layer is deposited over the first storage layer. The second regulating layer includes thermal regulators disposed over the second thermal layer wherein the thermal regulators regulate temperature.

The second storage layer includes one or more second thermal storage tanks disposed over the second regulating layer wherein each second thermal storage tank is capable of storing heat. The MSTEG system further includes a heat collecting surface deposited over the second storage layer, wherein the heat collecting surface is able to absorb heat from a heat source. In one aspect, heat dissipating channels are structured across multiple layers for heat transfer. It should be noted that each thermal storage tank disseminates stored heat across multiple layers via a predefined radiating schedule. The second TEG cell is configured to generate electricity at a higher temperature than the first TEG cell provides electricity. In one aspect, the first thermal storage tanks and the second thermal storage tanks are configured to store heat with different temperatures.

Referring back to FIG. 1, the MSTEG system is scalable and yields high output power depending on configuration. For example, a system with 3 layers of ITEG devices and 3 identical ITEG devices in each of the layer has a total of 9 ITEG devices and 3 types of ITEG devices with different thermal electric materials. The output power from a system with 3 layers of ITEG devices and 3 identical ITEG devices, for example, is greater than the output power from a system with 3 layers with one (1) ITEG device in each layer. Similarly, a system with 3 layers of ITEG devices and 1 ITEG device in each layer has a higher output power than a system with only 2 layers of ITEG device and 1 ITEG device for each layer.

Advantage of employing the embodiment(s) of the present invention using advance thermal-electric materials as well as built-in thermal storage device is to provide a simplified and cost effective method for generating power around the clock. While heat source can be any of solar, geo-thermal, hot steam from commercial power plant, industrial plants, and bio-fuel, MSTEG systems are able to generate electricity from a heat source with relatively few moving parts.

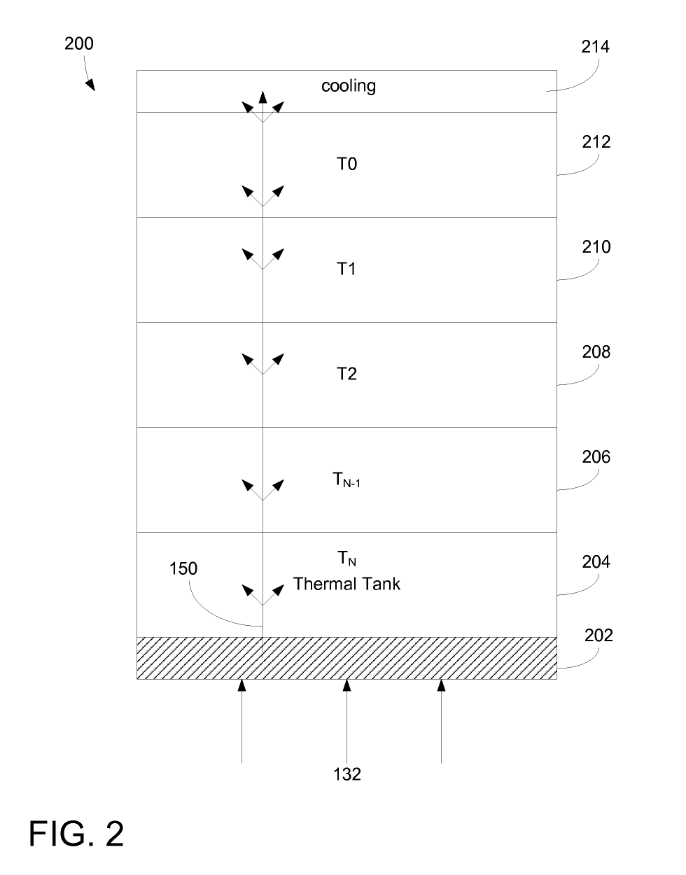

FIG. 2 is a block diagram 200 illustrating an MSTEG system using ITEG devices capable of operating at various temperature zones in accordance with one embodiment of the present invention. Diagram 200 includes a heat source 132 and an MSTEG system which includes seven planes 202-214. Each plane may include one or more thermal chambers that house multiple ITEG devices. In one embodiment, the MSTEG system further includes one or more thermal channels 150 wherein each thermal channel 150 allows heat to travel or bypass one or more planes or layers before reaching its destination. Thermal channel 150 is configured to transport different amount heat to different layers and/or planes. When the MSTEG system is over heating, thermal channel 150 releases extra heat from the system to a cooling layer 214. It should be noted that the underlying concept of the embodiment does not change if one or more planes or layers were added to or removed from diagram 200.

Plane 202 is similar to heat collection surface 102 shown in FIG. 1 and is a surface of the MSTEG system exposing to external thermal energy source 132 for heat absorption. Plane 204 is similar to thermal storage plane 104 shown in FIG. 1 capable of storing heat for a period of time. Planes 206-212 include four (4) thermal planes configured to operate in different temperature zones or ranges from T_{N} to T0. Similar to first thermal plane 106 illustrated in FIG. 1, each of planes 206-212 includes a regulating layer containing regulators and a thermal layer containing ITEG devices. Plane 214 is a cooling layer capable of providing overheating management for the MSTEG system. In one aspect, the cooling layer uses water to cool down the system whereby the cooling layer may provide warm or hot water while cooling down the system.

Thermal plane 206, in one embodiment, is configured to operate at a temperature range between T_{N} and T_{N-1}, whereas T_{N} represents the temperature at the N^{th} thermal plane, and N can be any real integer. T_{N}, for example, may be 1200° C. and T_{N-1} may be 900° C. While thermal plane 208 can be configured to operate at a temperature range between T_{N-1} and T2, thermal plane 210 operates at a temperature range between T2 to T1 whereas T_{N-1}, T2, and T1, for example, can be 900° C., 700° C., and 500° C., respectively. Furthermore, thermal plane 212 may be set to operate at a temperature range between 200° C. or below for generating electricity. Depending on materials used, the temperature range can change between the planes. Moreover, additional thermal plane(s) and/or thermal storage plane(s) can be added, merged, and/or removed, that is the N value can change accordingly depending on the system design specification.

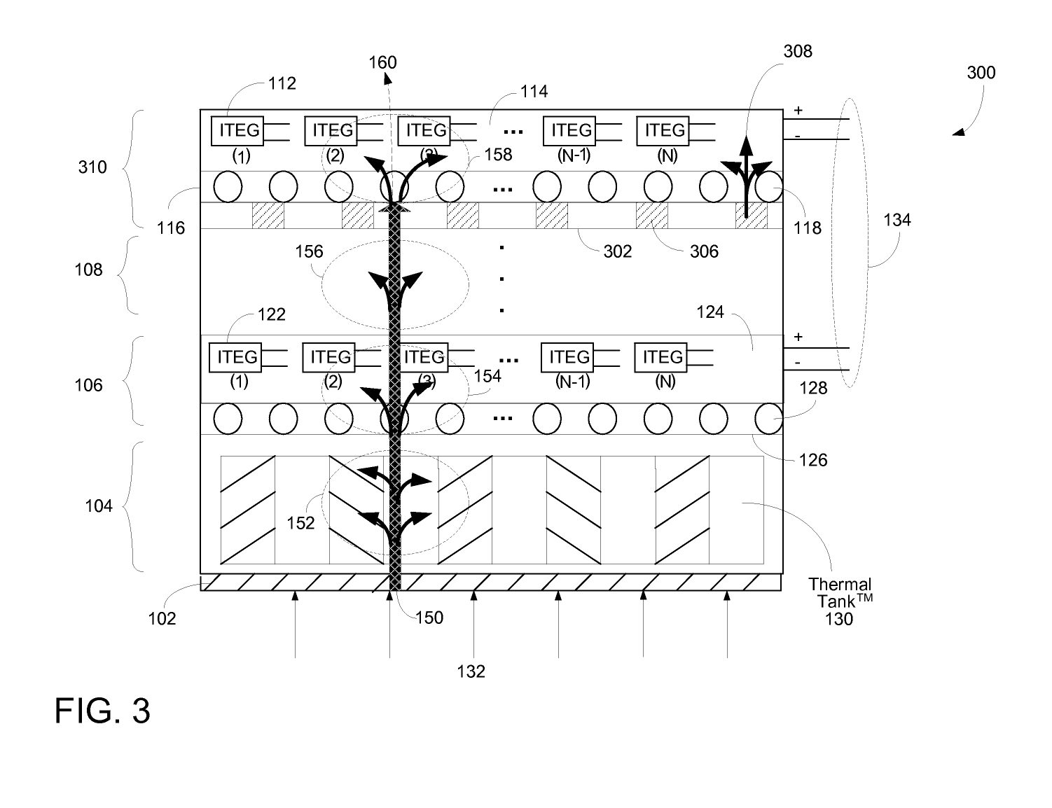

FIG. 3 is a block diagram 300 illustrating an MSTEG system using ITEG devices having multiple thermal storage layers in accordance with one embodiment of the present invention. Diagram 300 illustrate an thermal energy source 132 and the MSTEG system which includes a heat collecting surface 102, a thermal storage plane 104, a first thermal plane 106, a second thermal plane 110. Thermal energy source 132 can be solar thermal radiation, geo-thermal, and/or manmade heat sources. Note that an additional thermal plane or planes may be deposited or added in an area of 108.

The MSTEG system illustrated in FIG. 3 is similar to the MSTEG system shown in FIG. 1 except that the MSTEG system in diagram 300 includes multiple thermal storage layers 302. In one aspect, each thermal plane includes a storage layer 302, a regulating layer 116 or 126, and a thermal layer 114 or 124. Thermal storage layer 302, in one embodiment, includes one or more Thermal Tank™ 306 wherein each Thermal Tank™ 306 is able to release heat 308 when external heat supply diminishes. The ITEG device with Thermal Storage unit illustrates an efficient way of generating electricity through a consistent heat supply with or without sustained external heat supply.

A thermal regulated system is able to output desired output power using multiple thermal chambers and thermal regulators. The thermal chambers are used to house single or multiple TEG cells, as well as thermal regulators. The chambers, in one embodiment, are fabricated with insulation and heat reflector materials to prevent heat loss from the chambers. Thermal regulators are used to regulate the temperature within the thermal chambers inside a thermal regulated system and obtain optimum output of power by achieving a specific temperature range that matches with the type of thermal electric material used in the ITEG device. The desired output power is determined by the architecture of the thermal regulated system which includes multiple TEG cells, thermal chambers, and thermal regulators. It is to be appreciated that other implementations are possible (e.g., one or more of the planes may be combined with other planes and/or may not be necessary to perform one or more aspects of the present invention).

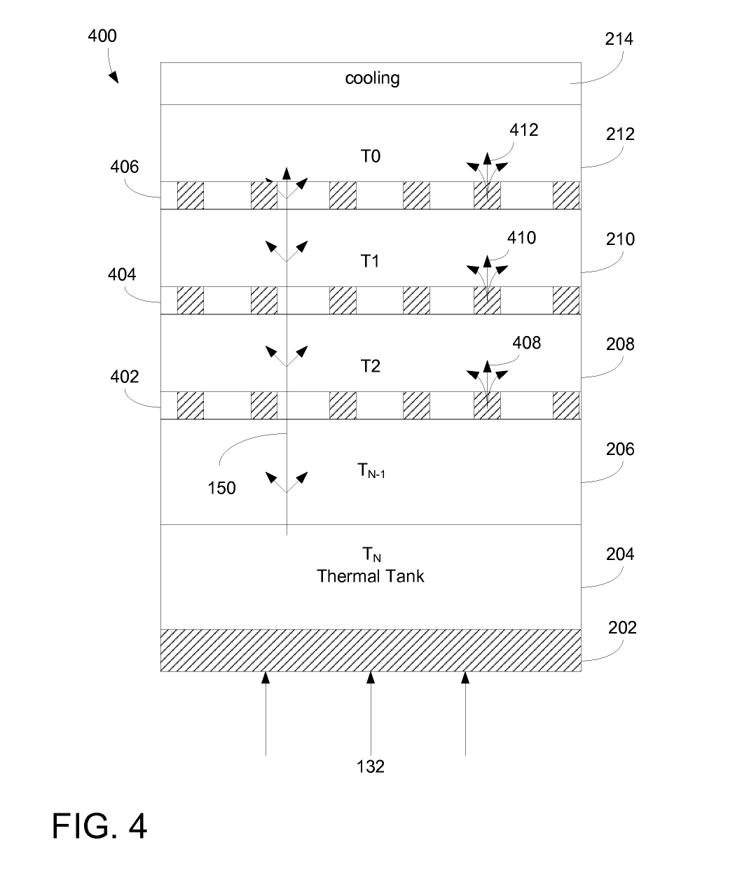

FIG. 4 is a block diagram 400 illustrating an MSTEG system using ITEG devices having multiple thermal storage tanks capable of operating in various temperature zones in accordance with one embodiment of the present invention. Diagram 400 includes a heat source 132 and an MSTEG system which further includes seven planes 202-214. Each plane may include one or more thermal chambers that house multiple ITEG devices. In one embodiment, the MSTEG system further includes one or more thermal channels 150 wherein thermal channel 150 allows heat to travel or bypass one or more planes or layers before reaching its destination. It should be noted that the underlying concept of the embodiment does not change if one or more planes or layers were added to or removed from diagram 400.

The MSTEG system illustrated in FIG. 4 is similar to the MSTEG system shown in FIG. 2 except that the MSTEG system in diagram 400 includes multiple thermal storage layers 402-406. In one aspect, each of thermal layers 402-406 includes one or more Thermal Tanks™ 306 for storing heat. Each of thermal layers 402-406 is capable of releasing heat 408-412 depending on ambient temperatures surrounding various thermal planes.

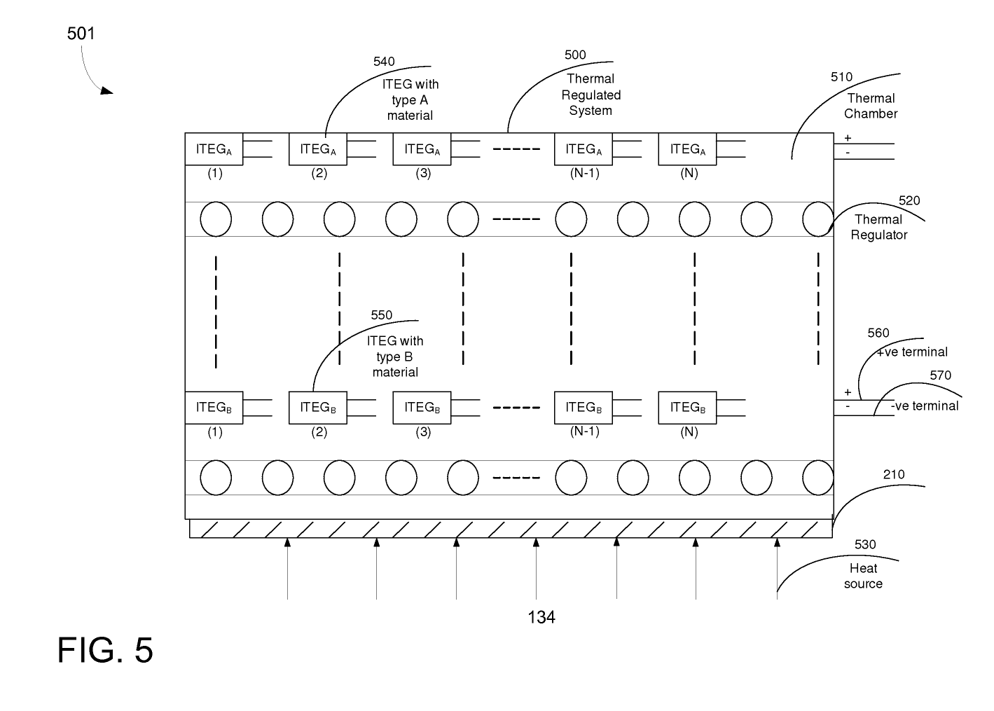

FIG. 5 is a block diagram 501 illustrating an MSTEG system using multiple thermal chambers and ITEG devices in accordance with one embodiment of the present invention. Thermal regulated system 500 includes multiple thermal chambers 510, multiple thermal regulators 520, and multiple ITEG devices 540 and 550. ITEG devices 540 and 550, in one example, are manufactured with different thermal electric materials whereby they can operate at different temperature ranges. Thermal regulators 520 are used to regulate the temperature in each of the thermal chambers for ITEG devices 540, 550. For example, ITEG_{B} 550 device has a thermal electric characteristic of operating at 700° C. while the ITEG_{A} 540 device has a thermal electric characteristic of operating temperature at 450° C. When heat is applied and is regulated in the first thermal chamber 510 at 700° C., the ITEG_{B} 550 devices yield more desirable efficiency with maximum output power. The excessive waste heat is then passed to the next thermal chamber 510 through thermal regulator 520 at a temperature of 450° C. ITEG_{A} 540 devices yields an optimum efficiency with maximum output power at a temperature range different from the temperature range operated by ITEG_{B} 550. The resulting output power is the summation of the power from two (2) separate layers of ITEG devices 540, 550. Note that the amount of output power may depend on the number of layers as well as the number of ITEG devices 540, 550 used in each layers.

Thermal Chamber 510 is a space that holds ITEG devices 540, 550 that generate electricity. Multiple layers of insulating materials and reflectors form the walls of the thermal chamber helping to minimize heat loss. The size of the thermal chamber 510 determines the maximum number of ITEG devices 540, 550 that it can hold. In addition, the effectiveness of its thermal insulating walls determines the duration of the heat that is retained inside the thermal chamber 510 to generate a constant and continuous supply of output power.

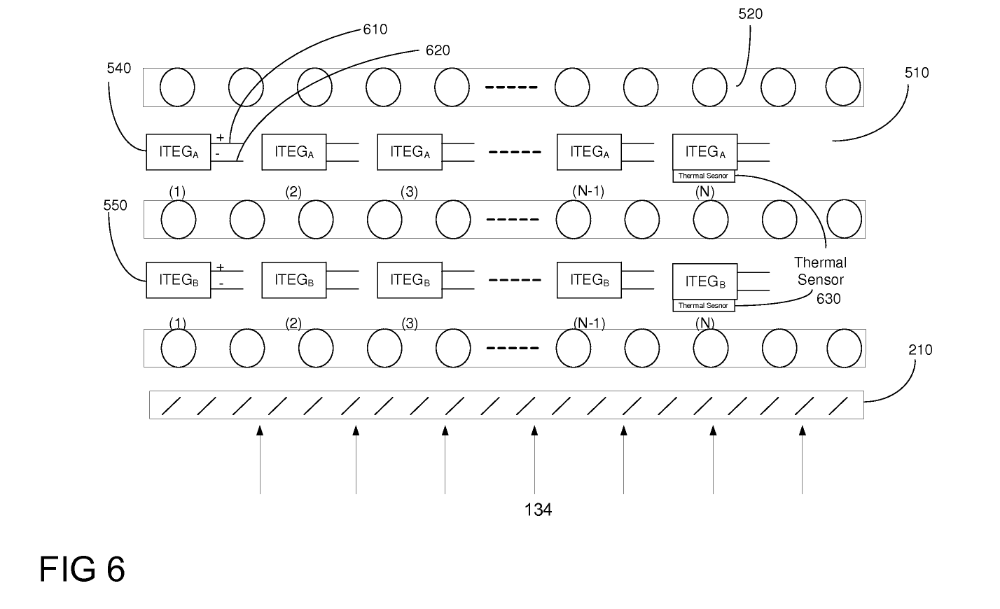

FIG. 6 is a block diagram illustrating an MSTEG system using ITEG devices with thermal sensors for monitoring temperature between the layers in accordance with one embodiment of the present invention. Thermal Regulator 520 separates between the two adjacent thermal chambers 510 holding ITEG devices 540, 550. There is a thermal sensor 630 at the hot side of ITEG device 540, 550 monitoring the temperature. When the temperature is too low to obtain optimum output power, it allows more heat flowing from the bottom layer to the current layer. On the contrary, when the temperature is too high, it stops the heat flow from the bottom layer and may even release heat to the upper layer trying to obtain the temperature required by the current layer of ITEG Device 540, 550 for optimum output power.

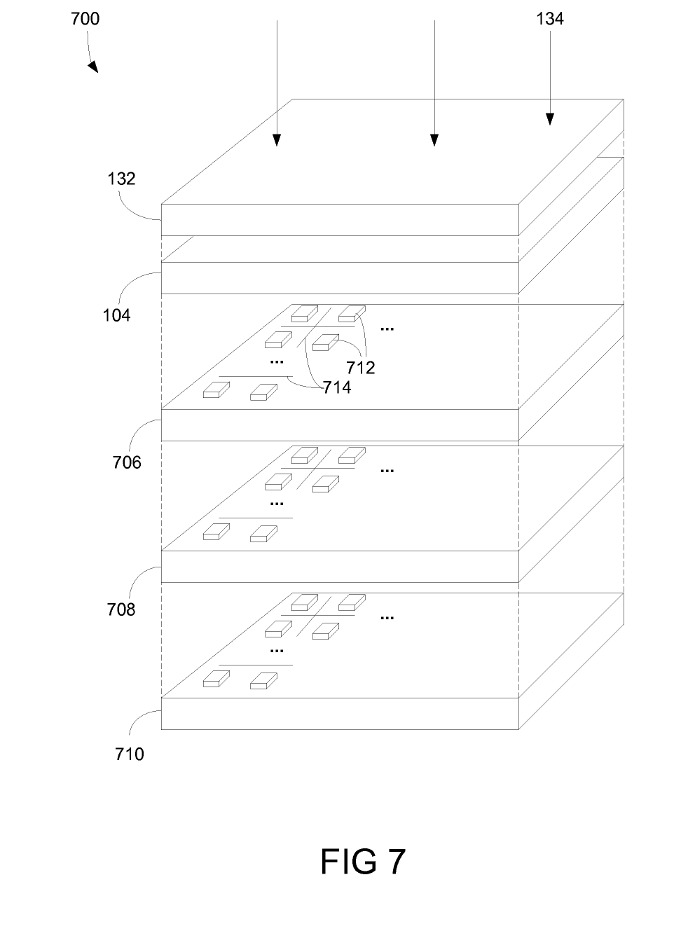

FIG. 7 is a three-dimensional (“3D”) diagram 700 illustrating an MSTEG system using ITEG devices in accordance with one embodiment of the present invention. Diagram 700 includes a heat source 134 and the MSTEG system which includes a heat collection surface 132, a thermal storage plane 104, and four (4) thermal planes 706-710. Each of thermal planes 706-710 includes multiple layers, not shown, and includes an array of ITEG devices 712 connected by connections 714. Depending on the applications, the size of M×N matrix of ITEG devices can vary. It should be noted that the underlying concept of the embodiment does not change if one or more layers or devices were added to or removed from diagram 700.

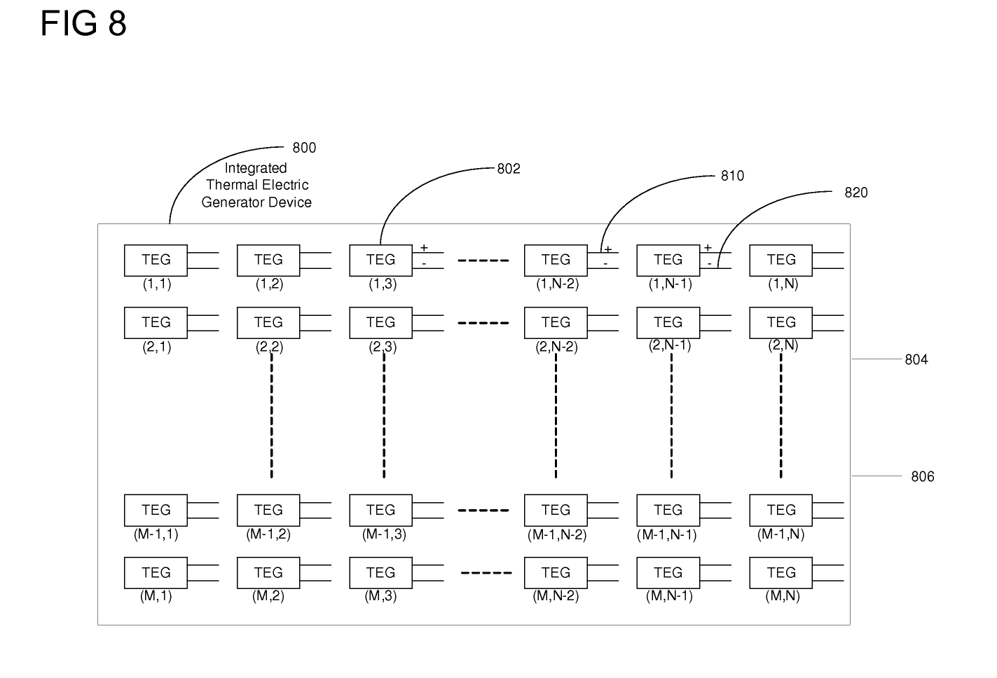

FIG. 8 is a block diagram illustrating a layout of ITEG device 800 using multiple TEG cells in accordance with one embodiment of the present invention. ITEG device 800 includes many small (or tiny) TEG cells 802 which are being arranged in an M×N matrix array configuration. Since the amount of output power for each of TEG cells 802 is quite small which may be in an order of milliwatt, connecting multiple TEG cells 802 in a matrix array can enhance the power output. The size of the M×N array depends on the desired physical size of the device and the amount of output power in terms of voltage (in volt) and current (in ampere) required. A collective or accumulative resultant of power output from an array of TEG cell 810 can be in an order of Watts and/or kilowatts. The positive output terminal 804 and the negative output terminal 806 are used for power output. An ITEG device with preset voltage and current outputs includes a basic TEG cell which can be duplicated into a large array of TEG cells to form an ITEG device. In one aspect, TEG cells in an M×N matrix array able to generate a preset voltage and current output through parallel and series configurations.

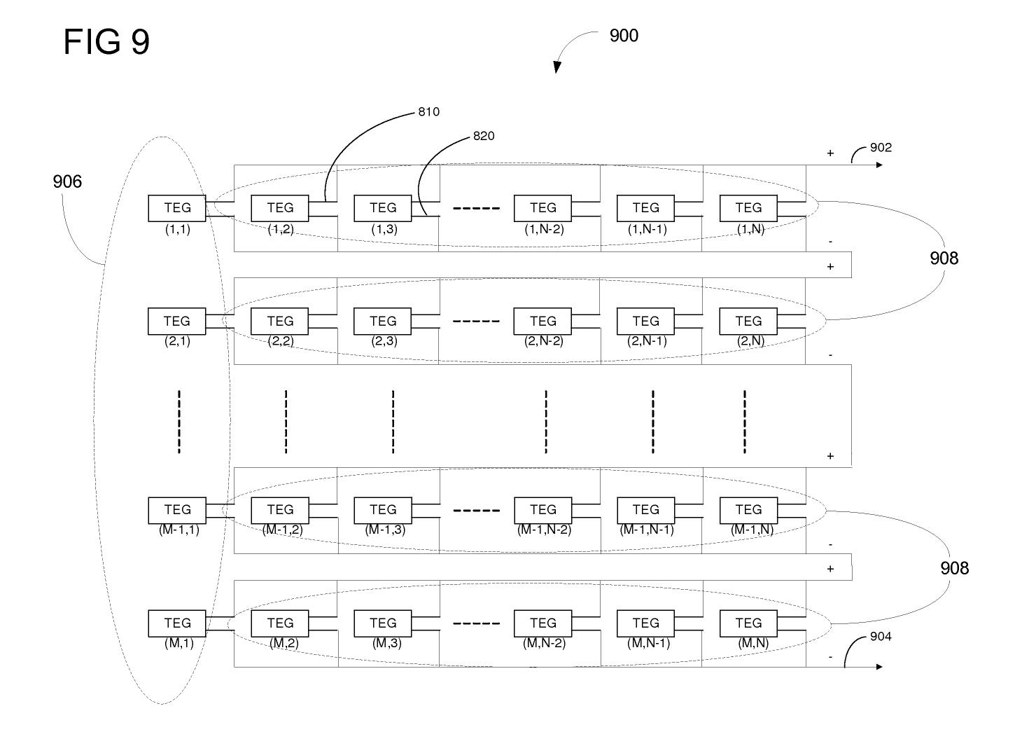

FIG. 9 is a block diagram 900 illustrating an array of TEG cells connected with a combination of series and parallel connections in accordance with one embodiment of the present invention. Diagram 900 includes a matrix of TEG cells disposed in a thermal chamber for generating electricity in response to the ambient temperature surrounding the thermal chamber. In one aspect, the matrix of TEG cells are interconnected by connections 810-820 and 902-904 wherein TEG cells are connected in series 906, parallel 908, or a combination of series 906 and parallel 908. Note that each of the TEG cells is able to generate a certain voltage (in volt) or current (in ampere) depending on the parallel or series configuration.

Referring to FIG. 9, the M×N array of TEG cells can be configured in parallels and/or series depending on the requirement of power output in terms of voltage and current. The parallel configuration of TEG cells generally provides a higher current output by summing individual output current from each of the parallel connected TEG cell. The series configuration of TEG cells general provides a higher output voltage by summing the individual output voltage from each of the series connected TEG cell. For example, if each TEG cell in a 50×40 matrix of TEG cells, wired in parallel for each row 908 and series for column 906 as shown in FIG. 9, is able to produce 100 millivolts with 150 milliamps, the voltage output for the matrix of TEG cells is 5 V (100×10⁻³×50=5.0V) and 6 A (150×10⁻³×40=6.0 A). The resultant output power is 5.0×6.0=30 Watts. It should be noted that the interconnect design is independent from individual TEG cell arranged in the matrix array. As such, flexible interconnection and/or programmable interconnection can provide additional flexibility and scalability for designing and implementing ITEG device.

The exemplary embodiment of the present invention includes various processing steps, which will be described below. The steps of the embodiment may be embodied in machine or computer executable instructions. The instructions can be used to cause a general purpose or special purpose system, which is programmed with the instructions, to perform the steps of the exemplary embodiment of the present invention. Alternatively, the steps of the exemplary embodiment of the present invention may be performed by specific hardware components that contain hard-wired logic for performing the steps, or by any combination of programmed computer components and custom hardware components. While embodiments of the present invention will be described with reference to the Internet, the method and apparatus described herein is equally applicable to other network infrastructures or other data communications environments.

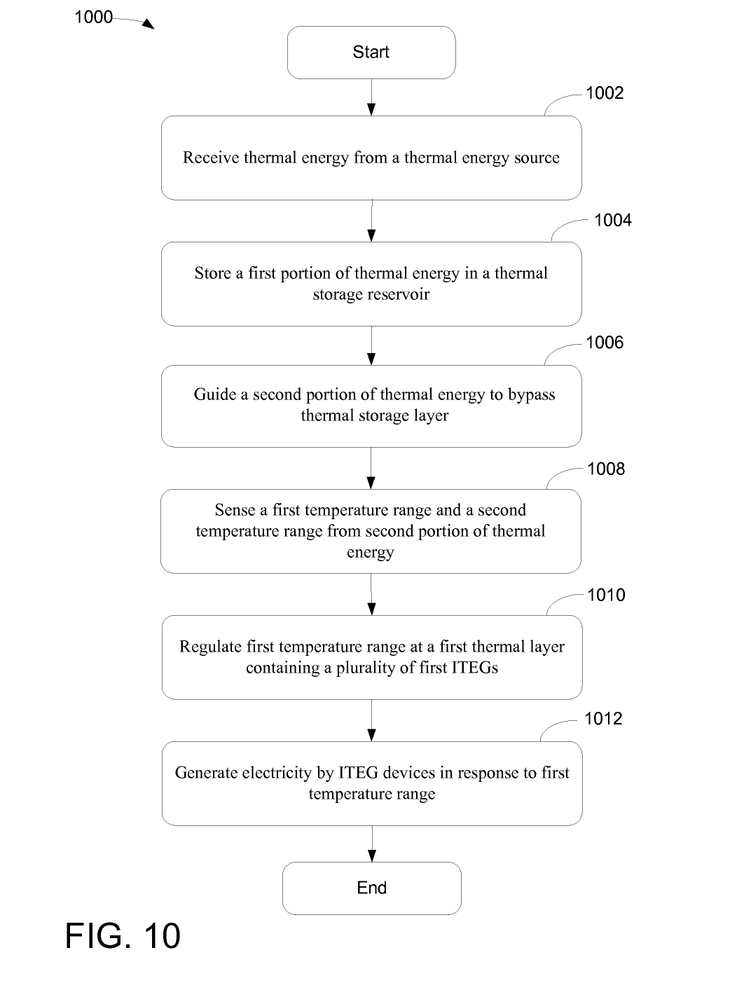

FIG. 10 is flowcharts 1000 illustrating a process for generating electricity via thermal energy through an MSTEG system in accordance with one embodiment of the present invention. At block 1002, a process capable of implementing functions provided by the MSTEG system is able to receive thermal energy from a thermal energy source. For example, the process is configured to absorb heat from solar source, geo-thermal source, industry plants, or bio-mess heat source.

At block 1004, the process stores a first portion of the thermal energy in a thermal storage reservoir, which is also known as Thermal Tank™. In one aspect, the process is able to store different heat at different thermal sub-storage reservoirs structured in a thermal storage layer or tank.

At block 1006, the process guides a second portion of the thermal energy to bypass a thermal storage layer containing at least one thermal storage reservoir via a heat dissipating channel or thermal channel. The process allows heat to radiate from a storage layer containing the thermal tanks to the first thermal layer.

At block 1008, the process is capable of sensing a first temperature range and a second temperature range from the second portion of the thermal energy. In one aspect, the temperature at each layer or plane is monitored by one or more temperature sensors.

At block 1010, the process regulates the first temperature range at a first thermal layer containing first ITEG devices. In one aspect, the process is capable of maintaining a predefined temperature range at the first thermal layer for electricity generation for a period of time.

At block 1012, the process is configured to generate electricity by the ITEG system(s) in response to the first temperature range. Upon sensing a first sub-range of the second temperature range and a second sub-range of the second temperature range, the process disseminates the first sub-range of the second temperature range at a second thermal layer containing the ITEG systems. The process generates electricity from the second ITEG systems in response to the first sub-temperature range.

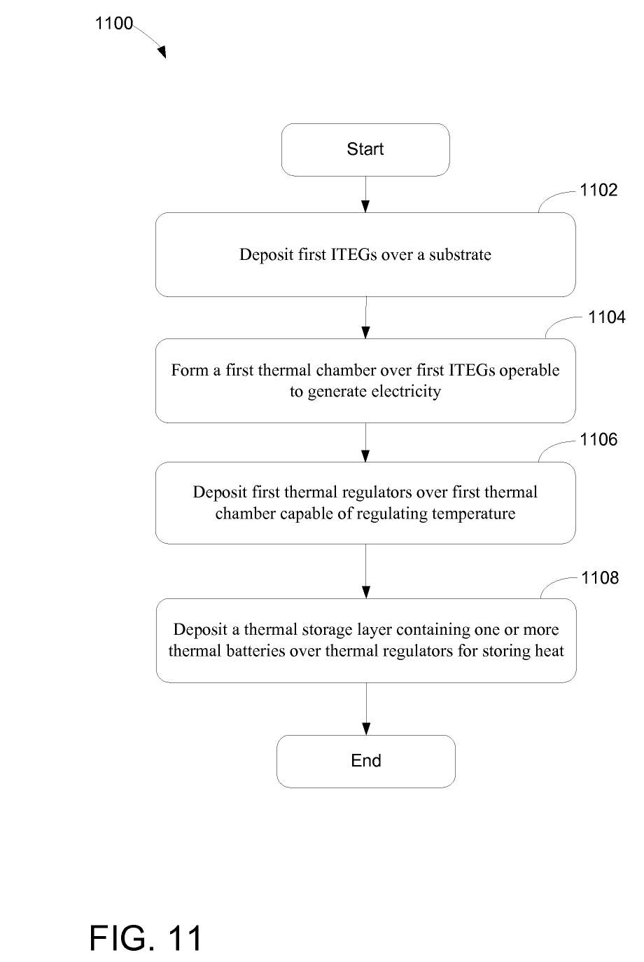

FIG. 11 is a flowchart 1100 illustrating a process for fabricating an MSTEG system in accordance with one embodiment of the present invention. The process, at block 1102, deposits multiple TEG cells over a substrate. At block 1104, the process forms a first thermal chamber over the first TEG cells operable to generate electricity. At block 1106, multiple first thermal regulators are deposited over the first thermal chamber capable of regulating temperature. Upon depositing second TEG cells over the multiple first thermal regulators, a second thermal chamber is formed over the second TEG cells operable to generate electricity. The process subsequently deposits second thermal regulators over the second thermal chamber capable of regulating temperature. At block 1108, a thermal storage layer containing one or more thermal batteries is deposited over the thermal regulators for storing heat. A heat collecting surface is deposited over the thermal storage layer for heat absorption.

From the description given above, one of the ordinary skills in the art will appreciate that the current design of such Integrated Thermal Electric Generator with Storage System that generates a high level of electricity around the clock, nights and days. The use of solar heat, heat energy from power plants, industrial plants, geo-thermal and bio-mess in producing electricity, helps the world in reducing the consumption of global natural resources such as fossil fuel, coal, et cetera. In addition, the materials used in the design has very little harmful substance unlike solar PV technology which uses silicon and silicon process technology that harms the environment upon disposing them at the end of its life span or when upgrading such systems. Since the heat sources are readily available from the natural environment, the availability of electricity for consumption, through the current design, is basically unlimited.

While particular embodiments of the present invention have been shown and described, it will be obvious to those of skills in the art that based upon the teachings herein, changes and modifications may be made without departing from this exemplary embodiment(s) of the present invention and its broader aspects. Therefore, the appended claims are intended to encompass within their scope all such changes and modifications as are within the true spirit and scope of this exemplary embodiment(s) of the present invention.

What is claimed is:

1. A device capable of generating electricity, comprising:
a first thermal layer including a plurality of first integrated thermal electric generator (“ITEG”) devices configured to generate electricity in response to a first thermal condition;
a first regulating layer including a plurality of thermal regulators deposited over the first thermal layer, wherein the plurality of thermal regulators regulate temperature;
a first storage layer including one or more first thermal storage tanks deposited over the first regulating layer, wherein each first thermal storage tank is capable of storing heat.

2. The device of claim 1, further comprising:
a second thermal layer including a plurality of second ITEG devices configured to generate electricity in response to a second thermal condition, wherein the second thermal layer is deposited over the first storage layer;
a second regulating layer including a plurality of thermal regulators disposed over the second thermal layer, wherein the plurality of thermal regulators regulate temperature;
a second storage layer including one or more second thermal storage tanks disposed over the second regulating layer, wherein each second thermal storage tank is capable of storing heat.

3. The device of claim 2, further comprising a heat collecting surface deposited over the second storage layer, wherein the heat collecting surface is able to absorb heat from a heat source.

4. The device of claim 3, further comprising a plurality of heat dissipating channels structured across multiple layers for heat transfer.

5. The device of claim 1, wherein the plurality of first ITEG devices is organized in an array configuration having at least a portion of the plurality of first ITEG devices are connected in series.

6. The device of claim 5, wherein the plurality of first ITEG devices is organized in an array configuration having at least a portion of the plurality of first ITEG devices are connected in parallel.

7. The device of claim 5, wherein the first thermal condition is temperature associated with the first thermal layer.

8. The device of claim 7,
wherein the plurality of thermal regulators includes a plurality of thermal sensors capable of detecting temperature; and
wherein the plurality of thermal regulators regulate temperature associated with the first thermal layer.

9. The device of claim 1, wherein each thermal storage tank disseminates stored heat across multiple layers via a predefined radiating schedule.

10. The device of claim 3, wherein the second TEG cell is configured to generate electricity at a higher temperature than electricity generated by the first TEG cell.

11. The device of claim 9, wherein the first thermal storage tanks and the second thermal storage tanks are configured to store heat with different temperatures.

12. A method for generating electricity, comprising:
receiving thermal energy from a thermal energy source;
storing a first portion of the thermal energy in a thermal storage reservoir;
guiding a second portion of the thermal energy to pass through a thermal storage layer containing at least one thermal storage reservoir via a heat dissipating channel;
sensing a first temperature range and a second temperature range from the second portion of the thermal energy;
regulating the first temperature range at a first thermal layer containing a plurality of first integrated thermal electric generators (“ITEG”) devices; and
generating electricity by the plurality of first ITEG devices in response to the first temperature range.

13. The method of claim 12, further comprising:
sensing a first sub-range of the second temperature range and a second sub-range of the second temperature range;
disseminating the first sub-range of the second temperature range at a second thermal layer containing a plurality of second ITEG devices; and
generating electricity by the plurality of second ITEG devices in response to the first sub-temperature range.

14. The method of claim 12, wherein receiving thermal energy from a thermal energy source includes absorbing heat from one of solar source, geo-thermal source, industry plants, and bio-mess.

15. The method of claim 14, wherein storing a first portion of the thermal energy in a thermal storage reservoir includes storing heat in a thermal tank.

16. The method of claim 15, wherein guiding a second portion of the thermal energy to pass through a thermal storage includes allowing heat to radiate from a storage layer containing the thermal tanks to the first thermal layer.

17. The method of claim 16, wherein regulating the first temperature range at a first thermal layer includes maintaining a predefined temperature range at the first thermal layer for electricity generation.

18. A method of fabricating an electric generator, comprising:
depositing a plurality of first integrated thermal electric generators (“ITEG”) devices over a substrate;
forming a first thermal chamber over the plurality of first ITEG devices operable to generate electricity;
depositing a plurality of first thermal regulators over the first thermal chamber capable of regulating temperature; and
depositing a thermal storage layer containing one or more thermal batteries over the plurality of thermal regulators for storing heat.

19. The method of claim 18, further comprising depositing a heat collecting surface over the thermal storage layer for heat absorption.

20. The method of claim 19, wherein depositing a plurality of first thermal regulators over the first thermal chamber further includes:
depositing a plurality of second ITEG devices over the plurality of first thermal regulator;
forming a second thermal chamber over the plurality of second ITEG devices operable to generate electricity; and
depositing a plurality of second thermal regulators over the second thermal chamber capable of regulating temperature.
